(19) United States
(12) Patent Application Publication
(10) Pub. No.: US 2026/0155102 A1
(43) Pub. Date: Jun. 4, 2026

(54) DISPLAY PANEL AND DRIVING METHOD THEREOF, AND DISPLAY APPARATUS

(71) Applicant: Wuhan Tianma Microelectronics Co., Ltd., Wuhan (CN)

(72) Inventors: Di ZHANG, Wuhan (CN); Dongxu Xiang, Wuhan (CN)

(73) Assignee: Wuhan Tianma Microelectronics Co., Ltd., Wuhan (CN)

(21) Appl. No.: 19/408,294

(22) Filed: Dec. 3, 2025

(30) Foreign Application Priority Data
Dec. 4, 2024 (CN) 202411775201.9

(51) Int. Cl. G09G 3/3233; G11C 19/28

(52) U.S. Cl. CPC G09G 3/3233; G11C 19/287; G09G 2300/0861; G09G 2310/0286; G09G 2310/08; G09G 2320/0233; G09G 2320/0247; G09G 2320/0257; G09G 2330/021

(57) ABSTRACT

Embodiments of the present application provide a display panel, a driving method, and a display apparatus. The display panel includes a pixel circuit including: a driving circuit; a first reset circuit, with a control terminal connected to a first scanning line, a first terminal connected to a first reset line, and a second terminal connected to a control terminal of the driving circuit; a data write circuit, with a control terminal connected to a second scanning line, a first terminal connected to a data line, and a second terminal connected to a first terminal of the driving circuit; and a first light-emitting control circuit, with a control terminal connected to a light-emitting control line, a first terminal connected to a second terminal of the driving circuit, and a second terminal connected to a light-emitting element; enable levels of the first scanning signal and the second scanning signal are low levels.

### CROSS-REFERENCE TO RELATED APPLICATION

The present application claims priority to Chinese Patent Application No. 202411775201.9 filed on Dec. 4, 2024, and titled “DISPLAY PANEL AND DRIVING METHOD THEREOF, AND DISPLAY APPARATUS”, which is incorporated herein by reference in its entirety.

### TECHNICAL FIELD

The present application relates to the field of display technology, and in particular, to a display panel and a driving method thereof, and a display apparatus.

### BACKGROUND

A display panel includes pixel circuits used to output driving current to light-emitting elements, so as to drive light-emitting elements to emit light. However, in the related art, poor driving methods for pixel circuits may lead to some display defects, thereby compromising display performance.

### SUMMARY

Embodiments of the present application provide a display panel and a driving method thereof, and a display apparatus, for optimizing driving methods for pixel circuits and improving display performance.

In a first aspect, embodiments of the present application provide a display panel, including a pixel circuit, and the pixel circuit includes:
a driving circuit;
a first reset circuit, a control terminal of the first reset circuit is electrically connected to a first scanning line configured to provide a first scanning signal, a first terminal of the first reset circuit is electrically connected to a first reset line, and a second terminal of the first reset circuit is electrically connected to a control terminal of the driving circuit;
a data write circuit, a control terminal of the data write circuit is electrically connected to a second scanning line configured to provide a second scanning signal, a first terminal of the data write circuit is electrically connected to a data line, and a second terminal of the data write circuit is electrically connected to a first terminal of the driving circuit; and
a first light-emitting control circuit, a control terminal of the first light-emitting control circuit is electrically connected to a light-emitting control line configured to provide a light-emitting control signal, a first terminal of the first light-emitting control circuit is electrically connected to a second terminal of the driving circuit, and a second terminal of the first light-emitting control circuit is electrically connected to a light-emitting element;
enable levels of the first scanning signal and the second scanning signal are low levels; within a time covered by one disable level of the light-emitting control signal, the second scanning signal has one enable level, and the total duration of the enable levels in the first scanning signal is longer than the duration of the enable level of the second scanning signal.

In a second aspect, based on the same inventive concept, embodiments of the present application further provide a driving method for a display panel, the display panel includes a pixel circuit, and the pixel circuit includes:
a driving circuit;
a first reset circuit, a control terminal of the first reset circuit is electrically connected to a first scanning line configured to provide a first scanning signal, a first terminal of the first reset circuit is electrically connected to a first reset line, and a second terminal of the first reset circuit is electrically connected to a control terminal of the driving circuit;
a data write circuit, a control terminal of the data write circuit is electrically connected to a second scanning line configured to provide a second scanning signal, a first terminal of the data write circuit is electrically connected to a data line, and a second terminal of the data write circuit is electrically connected to a first terminal of the driving circuit; and
a first light-emitting control circuit, a control terminal of the first light-emitting control circuit is electrically connected to a light-emitting control line configured to provide a light-emitting control signal, a first terminal of the first light-emitting control circuit is electrically connected to a second terminal of the driving circuit, and a second terminal of the first light-emitting control circuit is electrically connected to a light-emitting element;
enable levels of the first scanning signal and the second scanning signal are low levels;
the driving method includes: within a time covered by one disable level of the light-emitting control signal, controlling the second scanning signal to output one enable level, and controlling the total duration of the enable levels in the first scanning signal to be longer than the duration of the enable level of the second scanning signal.

In a third aspect, based on the same inventive concept, embodiments of the present application further provide a display apparatus, including the foregoing display panel.

The technical solutions provided by the embodiments of the present application achieve the following beneficial effects.

In the embodiments of the present application, within the time covered by the single high level of the light-emitting control signal, the total duration of the low levels in the first scanning signal is relatively long, and thus the first reset transistor resets the gate of the driving transistor for a longer time, thereby restoring the driving transistor to its initial working state to a greater extent and restoring the threshold voltage of the driving transistor to a normal level. Furthermore, during gray-scale switching, the driving transistor may be quickly in a normal state, thereby effectively solving the problems of short-term afterimages and brightness difference in the first frame. Meanwhile, within the time covered by the single high level of the light-emitting control signal, the second scanning signal has only one low level, thus voltage is written to the driving transistor only once, and the written voltage is the data voltage required by the driving transistor. In this way, the node potential of the driving transistor will not be affected by a display signal in the previous circuit row, thereby avoiding black-on-bright bars.

In addition, the second scanning signal outputs fewer pulses in the embodiments of the present application, which can reduce panel power consumption to a certain extent.

### BRIEF DESCRIPTION OF THE DRAWINGS

In order to explain the technical solutions in the embodiments of the present application or in the prior art, the accompanying drawings required for use in the description of the embodiments or the prior art will be simply introduced below. Apparently, the accompanying drawings described below show some embodiments of the present application. For those skilled in the art, other drawings may be derived from these drawings without any creative efforts.

FIG. 1 is a schematic structural diagram of a display panel in the related art;

FIG. 2 is a schematic structural diagram of a pixel circuit in the related art;

FIG. 3 is a timing diagram in the related art;

FIG. 4 is a schematic structural diagram of a display panel according to an embodiment of the present application;

FIG. 5 is a schematic structural diagram of a pixel circuit according to an embodiment of the present application;

FIG. 6 is a timing diagram according to an embodiment of the present application;

FIG. 7 is a box diagram according to an embodiment of the present application;

FIG. 8 is a box diagram according to another embodiment of the present application;

FIG. 9 is a timing diagram according to another embodiment of the present application;

FIG. 10 is a schematic structural diagram of a first shift unit according to an embodiment of the present application;

FIG. 11 is a timing diagram corresponding to FIG. 10;

FIG. 12 is a schematic structural diagram of a second shift unit according to an embodiment of the present application;

FIG. 13 is a timing diagram corresponding to FIG. 12;

FIG. 14 is a schematic structural diagram of a display panel according to another embodiment of the present application;

FIG. 15 is a timing diagram according to yet another embodiment of the present application;

FIG. 16 is a timing diagram according to yet another embodiment of the present application;

FIG. 17 is a schematic structural diagram of a pixel circuit according to another embodiment of the present application;

FIG. 18 is a timing diagram according to yet another embodiment of the present application;

FIG. 19 is a schematic structural diagram of a pixel circuit according to yet another embodiment of the present application;

FIG. 20 is a schematic structural diagram of a pixel circuit according to yet another embodiment of the present application;

FIG. 21 is a timing diagram according to yet another embodiment of the present application;

FIG. 22 is a timing diagram according to yet another embodiment of the present application;

FIG. 23 is a schematic structural diagram of a display panel according to yet another embodiment of the present application;

FIG. 24 is a timing diagram according to yet another embodiment of the present application;

FIG. 25 is a schematic structural diagram of a pixel circuit according to yet another embodiment of the present application; and

FIG. 26 is a schematic structural diagram of a display apparatus according to an embodiment of the present application.

### DETAILED DESCRIPTION

To better understand the technical solutions of the present application, the embodiments of the present application are detailed below with reference to the accompanying drawings.

It should be noted that the described embodiments are merely some but not all of the embodiments of the present application. All other embodiments obtained by those of ordinary skill in the art based on the embodiments of the present application without any creative efforts fall within the scope of protection of the present application.

The terms used in the embodiments of the present application are merely for the purpose of illustrating specific embodiments, and are not intended to limit the present application. The terms “a”, “the”, and “this” of singular forms used in the embodiments and the appended claims of the present application are also intended to include plural forms, unless otherwise specified in the context clearly.

Understandably, the term “and/or” used below is only an associative relationship for describing associated objects, indicating three relationships. For example, A and/or B may indicate three situations: A exists alone; A and B exist at the same time; and B exists alone. In addition, the character “/” herein generally indicates an “or” relationship between contextually associated objects.

Before the technical solutions provided by the embodiments of the present application are elaborated, the present application first explains the problems existing in the related art.

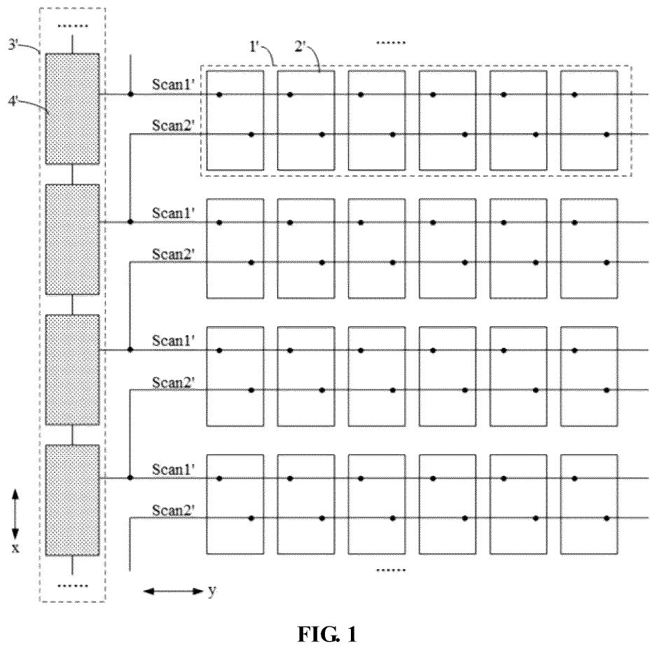

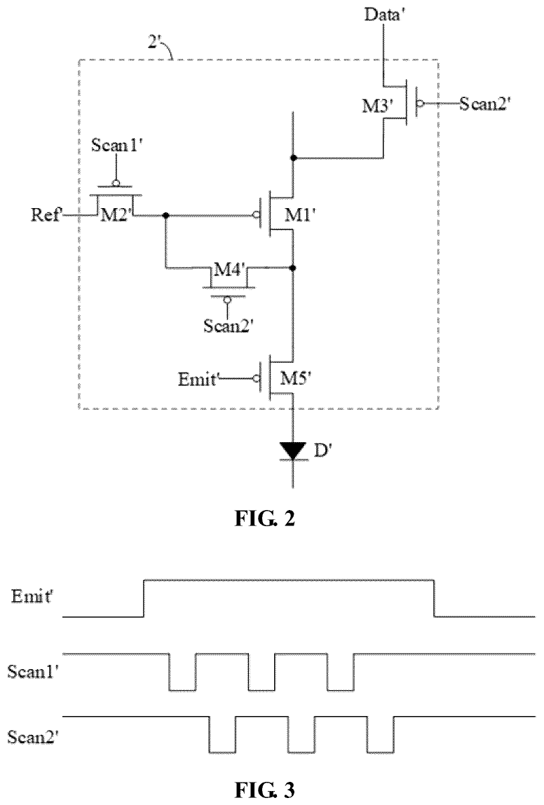

As shown in FIGS. 1 and 2, FIG. 1 is a schematic structural diagram of a display panel in the related art, and FIG. 2 is a schematic structural diagram of a pixel circuit in the related art. The display panel includes a plurality of circuit rows 1′ arranged along a first direction x, the circuit row 1′ includes a plurality of pixel circuits 2′ arranged along a second direction y, and the first direction x intersects with the second direction y.

The pixel circuit 2′ includes a driving transistor M1′, a first reset transistor M2′, a data write transistor M3′, a threshold compensation transistor M4′, and a first light-emitting control transistor M5′.

The first reset transistor M2′ has a gate electrically connected to a first scanning line Scan1′, a first electrode electrically connected to a reset line Ref, and a second electrode electrically connected to a gate of the driving transistor M1′. The data write transistor M3′ has a gate electrically connected to a second scanning line Scan2′, a first electrode electrically connected to a data line Data′, and a second electrode electrically connected to a first electrode of the driving transistor M1′. The threshold compensation transistor M4′ has a gate electrically connected to the second scanning line Scan2′, a first electrode electrically connected to a second electrode of the driving transistor M1′, and a second electrode electrically connected to the gate of the driving transistor M1′. The first light-emitting control transistor M5′ has a gate electrically connected to a light-emitting control line Emit′, a first electrode electrically connected to the second electrode of the driving transistor M1′, and a second electrode electrically connected to a light-emitting element D′.

When the display panel performs gray-scale switching, the hysteresis effect of the driving transistor M1′ may lead to short-term afterimages and differences in brightness between a first frame and subsequent frames after switching. FIG. 3 is a timing diagram in the related art. To solve these adverse problems, as shown in FIG. 3, the related art proposes that, within a time covered by one high level of a light-emitting control signal, both a first scanning signal and a second scanning signal perform multi-pulse driving, such as three-phase driving, enabling multiple resets and voltage writes for the driving transistor M1′ to achieve the purpose of repeatedly refreshing the node potential of the driving transistor M1′.

For example, in one structure, as shown in FIG. 1, the display panel further includes a shift register 3′, and the shift register 3′ includes a plurality of shift units 4′ that are cascaded. One shift unit 4′ is electrically connected to both the second scanning line Scan2′ corresponding to the previous circuit row 1′ and the first scanning line Scan1′ corresponding to the next circuit row 1′. By controlling the shift unit 3′ for multi-pulse output, the multi-pulse driving by the first scanning signal and the second scanning signal is enabled.

Alternatively, in other structures, the display panel may further include at least two sets of shift registers, where one set of shift registers is electrically connected to the first scanning line Scan1′ to control the first scanning line Scan1′ for multi-pulse driving, and the other set of shift registers is electrically connected to the second scanning line Scan2′ to control the second scanning line Scan2′ for multi-pulse driving.

However, the inventor found during research that, in the process of multiple voltage writes by the driving transistor M1′, in the first several writes, the data line Data′ transmits data voltage required by the pixel circuits 2′ in the previous circuit row 1′, so the voltage written in the first several writes is the data voltage corresponding to the pixel circuits 2′ in the previous circuit row 1′, and the data voltage corresponding to the circuit row 1′ is written only in the last write. As a result, the voltage write of the circuit row 1′ will be affected by the display signals of other circuit rows 1′.

For example, when the previous circuit row 1′ needs to display a black pattern and the current circuit row 1′ needs to display a white pattern, the data voltage required by the pixel circuits 2′ in the previous circuit row 1′ is higher, while the data voltage required by the pixel circuits 2′ in the current circuit row 1′ is lower. For example, the data voltage corresponding to the pixel circuits 2′ in the previous circuit row 1′ is 7 V, while the data voltage corresponding to the pixel circuits 2′ in the current circuit row 1′ is 3 V Then, during the first few resets and voltage writes of the driving transistors M1′ of the pixel circuits 2′ in the current circuit row 1′, the gate voltage of the driving transistors M1′ is very high, resulting in more severe negative bias of the driving transistors M1′. Therefore, when the data voltage required by the current circuit row 1′ is written in the last time, the brightness may be relatively high due to insufficient voltage write, resulting in poor display of black-on-bright bars on the display panel.

In view of this, embodiments of the present application propose a technical solution that can effectively solve the problems of short-term afterimages and brightness difference in the first frame and avoid black-on-bright bars.

Embodiments of the present application provide a display panel. The display panel may be various types of display panels, such as organic light-emitting diode (OLED), active matrix organic light-emitting diode (AMOLED), and light-emitting diode (LED) display panels.

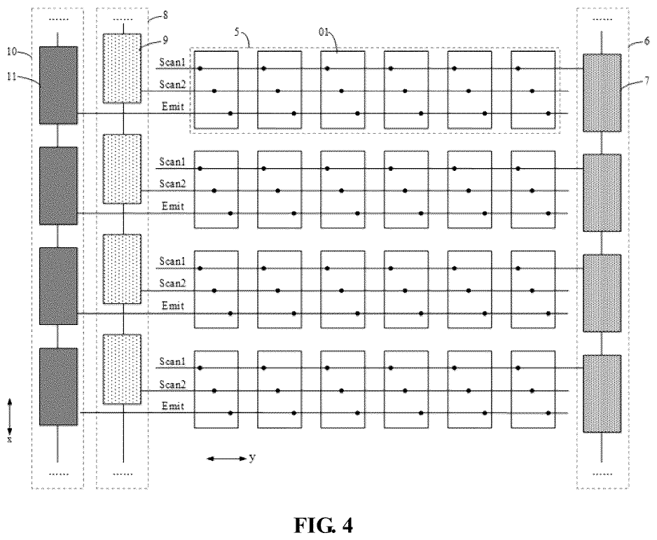

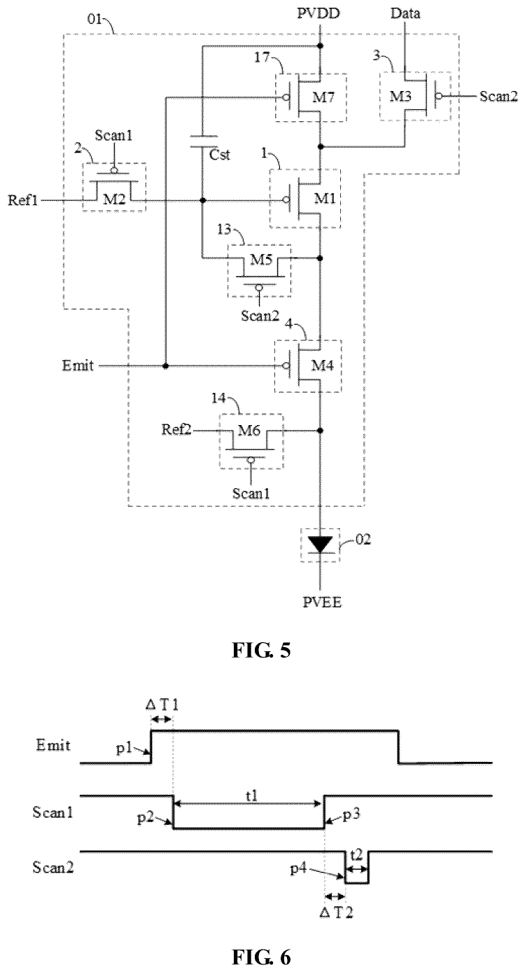

As shown in FIGS. 4 and 5, FIG. 4 is a schematic structural diagram of a display panel according to an embodiment of the present application, and FIG. 5 is a schematic structural diagram of a pixel circuit according to an embodiment of the present application. The display panel includes a pixel circuit 01 and a light-emitting element 02.

The pixel circuit 01 includes a driving circuit 1, a first reset circuit 2, a data write circuit 3, and a first light-emitting control circuit 4.

A control terminal of the first reset circuit 2 is electrically connected to a first scanning line Scan1 configured to provide a first scanning signal, a first terminal of the first reset circuit 2 is electrically connected to a first reset line Ref1, and a second terminal of the first reset circuit 2 is electrically connected to a control terminal of the driving circuit 1.

A control terminal of the data write circuit 3 is electrically connected to a second scanning line Scan2 configured to provide a second scanning signal, a first terminal of the data write circuit 3 is electrically connected to a data line Data, and a second terminal of the data write circuit 3 is electrically connected to a first terminal of the driving circuit 1.

A control terminal of the first light-emitting control circuit 4 is electrically connected to a light-emitting control line Emit configured to provide a light-emitting control signal, a first terminal of the first light-emitting control circuit 4 is electrically connected to a second terminal of the driving circuit 1, and a second terminal of the first light-emitting control circuit 4 is electrically connected to the light-emitting element 02.

FIG. 6 is a timing diagram according to an embodiment of the present application. As shown in FIG. 6, enable levels of the first scanning signal and the second scanning signal are low levels. Within a time covered by one disable level of the light-emitting control signal, the second scanning signal has one enable level, and the total duration of the enable levels in the first scanning signal is longer than the duration of the enable level of the second scanning signal.

More specifically, the driving circuit 1 includes a driving transistor M1. The first reset circuit 2 includes a first reset transistor M2, and the first reset transistor M2 has a gate electrically connected to the first scanning line Scan1, a first electrode electrically connected to the first reset line Ref1, and a second electrode electrically connected to a gate of the driving transistor M1. The data write circuit 3 includes a data write transistor M3, and the data write transistor M3 has a gate electrically connected to the second scanning line Scan2, a first electrode electrically connected to the data line Data, and a second electrode electrically connected to a first electrode of the driving transistor M1. The first light-emitting control circuit 4 includes a first light-emitting control transistor M4, and the first light-emitting control transistor M4 has a gate electrically connected to the light-emitting control line Emit, a first electrode electrically connected to a second electrode of the driving transistor M1, and a second electrode electrically connected to the light-emitting element 02.

In the embodiments of the present application, the first scanning signal has a low enable level and a high disable level, and the second scanning signal has a low enable level and a high disable level. This means that both the first reset transistor M2 and the data write transistor M3 are P-type transistors, such as low temperature poly-silicon (LTPS) transistors with better device stability. The first reset transistor M2 is turned on in response to the low level of the first scanning signal, and writes a reset voltage to a gate of the driving circuit 1. The data write transistor M3 is turned on in response to the low level of the second scanning signal, and writes a data voltage to a first electrode of the driving circuit 1.

In addition, the light-emitting control signal may also have a low enable level and a high disable level. At this point, the first light-emitting control transistor M4 may also be an LTPS transistor. The first light-emitting control transistor M4 is turned on in response to the low level of the light-emitting control signal, and transmits driving current converted by the driving transistor M1 to the light-emitting element 02.

In the embodiments of the present application, within the time covered by the single high level of the light-emitting control signal, the total duration of the low levels in the first scanning signal is longer than the duration of the low level of the second scanning signal, so the first reset transistor M2 can reset the driving transistor M1 for a longer time, thereby improving the reset capability for the driving transistor M1, restoring the driving transistor to its initial working state to a greater extent, and restoring the threshold voltage of the driving transistor to a normal level. Furthermore, during gray-scale switching, the driving transistor M1 may be quickly in a normal state, thereby effectively solving the problems of short-term afterimages and brightness difference in the first frame. Meanwhile, within the time covered by the single high level of the light-emitting control signal, the second scanning signal has only one low level, that is, voltage is written to the driving transistor M1 only once, and the written voltage is the data voltage required by the driving transistor. In this way, the node potential of the driving transistor M1 will not be affected by a display signal in the previous circuit row, thereby avoiding black-on-bright bars.

In addition, compared to the related art, the second scanning signal outputs fewer pulses in the embodiments of the present application, which can reduce panel power consumption to a certain extent.

It should be noted that the embodiments of the present application utilizes two sets of different shift registers to separately drive the first scanning line Scan1 and the second scanning line Scan2, so as to design the timing of the first scanning signal and the second scanning signal differently, thereby achieving the purposes of eliminating afterimages and brightness difference in the first frame and preventing the occurrence of black-on-bright bars.

In a feasible embodiment, combining FIGS. 5 and 6, within the time covered by one disable level of the light-emitting control signal, the first scanning signal has one enable level, and the enable level of the first scanning signal is prior to the enable level of the second scanning signal.

The duration of the enable level of the first scanning signal is t1, and the duration of the enable level of the second scanning signal is t2, where t1>t2.

Based on this driving method, within the time covered by one disable level of the light-emitting control signal, both the first scanning signal and the second scanning signal perform single-pulse driving. The single low level of the first scanning signal has relatively long duration, and the first scanning signal drives the first reset transistor M2 to be turned on for a long time and continuously resets the driving transistor M1 for a relatively long time, so that the driving transistor M1 is restored to its initial working state to a greater extent, thereby effectively solving the problems of afterimages and brightness difference in the first frame during gray-scale switching. Moreover, compared to the related art, such driving results in fewer pulses output by the first scanning signal, which can further reduce panel power consumption, for example, by about 10 mW.

In a feasible embodiment, t1>2×t2. Therefore, the duration of the low level of the first scanning signal is significantly extended to ensure sufficient reset time for the driving transistor M1.

In the display process, circuit rows 5 are scanned one by one. The scanning time for a single circuit row 5 may be defined as row time H, where

$$H = \frac{1}{f \times n} ,$$

Herein, n represents the number of rows of the pixel circuits 01 in the display panel. That is, with reference to FIG. 4, the display panel includes a plurality of circuit rows 5 arranged along the first direction x, and the circuit row 5 includes a plurality of pixel circuits 01 arranged along the second direction y intersecting with the first direction x, and n is the number of circuit rows 5.

Here, f is a base frequency or a current driving frequency of the display panel.

Regarding the value of f, in one case, the display panel has a base frequency, and other lower frequency drives are implemented by decreasing the base frequency. For example, the base frequency is 120 Hz, and one frame is 8.33 ms. When the display panel needs to be driven by 60 Hz, a data refresh cycle at 60 Hz includes two frames, one of which is a write frame and the other one is a hold frame. When the display panel needs to be driven by 30 Hz, a data refresh cycle at 30 Hz includes four frames, one of which is a write frame and the other three are hold frames. In this case, the scanning time for the circuit row 5 is the frame corresponding to the base frequency divided by the number of circuit rows 5. Therefore, the value of f in the equation is the base frequency.

In another case, the lower frequency drives are not implemented by decreasing the frequency, but the duration of the data refresh cycle corresponding to the lower frequency is extended by increasing the scanning time for the circuit row 5. For example, when the display panel needs to be driven by 60 Hz, one data refresh cycle at 60 Hz is one frame, which is 16.67 ms. When the display panel needs to be driven by 30 Hz, one data refresh cycle at 30 Hz is one frame, which is 33.33 ms. In this case, the scanning time for the circuit row 5 is the frame corresponding to the current driving frequency divided by the number of circuit rows 5. Therefore, the value of f in the equation is the current driving frequency of the display panel.

In the embodiments of the present application, t2 may be equal to 1H, and accordingly, t1≥2H.

Further, t1≤20×t2. As mentioned earlier, when t2=1H, t1 satisfies: 2H≤t1≤20H. For example, t1 may be equal to 2H, 4H, 8H, or 12H.

On the premise that the short-term afterimages and the brightness difference in the first frame can be eliminated, t1 should not be designed too large. If t1 is too large, the light-emitting control signal needs to further extend its high-level duration to ensure that it can completely cover the low level of the first scanning signal and the low level of the second scanning signal, but this will reduce the light-emitting time. The light-emitting time affects human eye's perception on brightness changes. If the light-emitting time is too short, the brightness changes rapidly, and the human eye may be more likely to perceive strobing. To ensure superior stroboscopic effect visibility measurement (SVM), t1 may be designed to be less than or equal to 20×t2.

In this regard, the embodiments of the present application conducted tests.

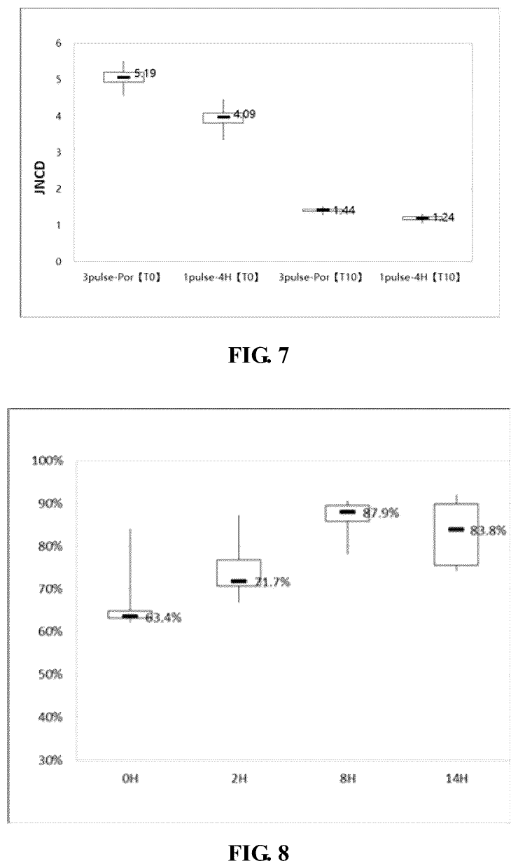

As shown in FIG. 7, which is a box diagram according to an embodiment of the present application, the vertical axis “IJNCD” in FIG. 7 represents minimum perceptible chromatic aberration, which can be used to reflect the short-term afterimage capability. The larger the value, the more obvious the short-term afterimage will be. In the horizontal axis of FIG. 7, [T0] represents instantaneous afterimage capability of black-to-white shifting, [T10] represents afterimage capability after 10 seconds of black-to-white shifting, “3 pulse-POR” represents that the first scanning signal outputs three low levels within the time covered by one high level of the light-emitting control signal in the related art and the duration of a single low level is 1H, and “1 pulse-4H” represents that the first scanning signal outputs one low level within the time covered by one high level of the light-emitting control signal in the embodiments of the present application and the duration of the low level is 4H.

According to FIG. 7, it can be seen that compared to the related art, based on the design of the first scanning signal in the embodiments of the present application, the JNCD value significantly decreases and the short-term afterimage is significantly eliminated. For example, compared to “3 pulse-POR [T0]”, the JNCD corresponding to “1 pulse-4H [T0]” decreases from 5.19 to 4.09.

As shown in FIG. 8, which is a box diagram according to another embodiment of the present application, where the percentage represented by the vertical axis of FIG. 8 is the percentage of the actual brightness of the first frame to the target brightness. The larger the value, the closer the actual brightness of the first frame is to the target brightness, and the smaller the brightness difference between the first frame and other frames. The horizontal axis is t1, that is, in the embodiments of the present application, within the time covered by one high level of the light-emitting control signal, the first scanning signal outputs one low level, and the horizontal axis represents the duration of the low level of the first scanning signal.

According to FIG. 8, it can be seen that when t1 increases to above 2H, the actual brightness of the first frame is significantly improved, and is closer to the target brightness.

In a feasible embodiment, with reference to FIG. 6, a time point when the light-emitting control signal transitions from the enable level to the disable level is a first time point p1, a time point when the first scanning signal transitions from the disable level to the enable level is a second time point p2, and the interval between the first time point p1 and the second time point p2 is ΔT1, where 0<ΔT1≤1H.

A time point when the first scanning signal transitions from the enable level to the disable level is a third time point p3, a time point when the second scanning signal transitions from the disable level to the enable level is a fourth time point p4, and the interval between the third time point p3 and the fourth time point p4 is ΔT2, where 0<ΔT2≤1H.

$$H = \frac{1}{f \times n} ,$$

where n represents the number of rows of the pixel circuits 01 in the display panel, and f represents the base frequency or the current driving frequency of the display panel. The definition of row time H is detailed in the foregoing embodiment and will not be repeated here.

When ΔT1 and ΔT2 satisfy the above limitations, the interval between the low transition of the first scanning signal and the high transition of the light-emitting control signal is at most 1H, and the time interval between the two is relatively short. Meanwhile, the interval between the high transition of the first scanning signal and the low transition of the second scanning signal is also at most 1H, and the time interval between the two is also relatively short. Then, under the condition that the high level of the light-emitting control signal has definite duration, the duration of the low level of the first scanning signal can be further extended to increase the reset time.

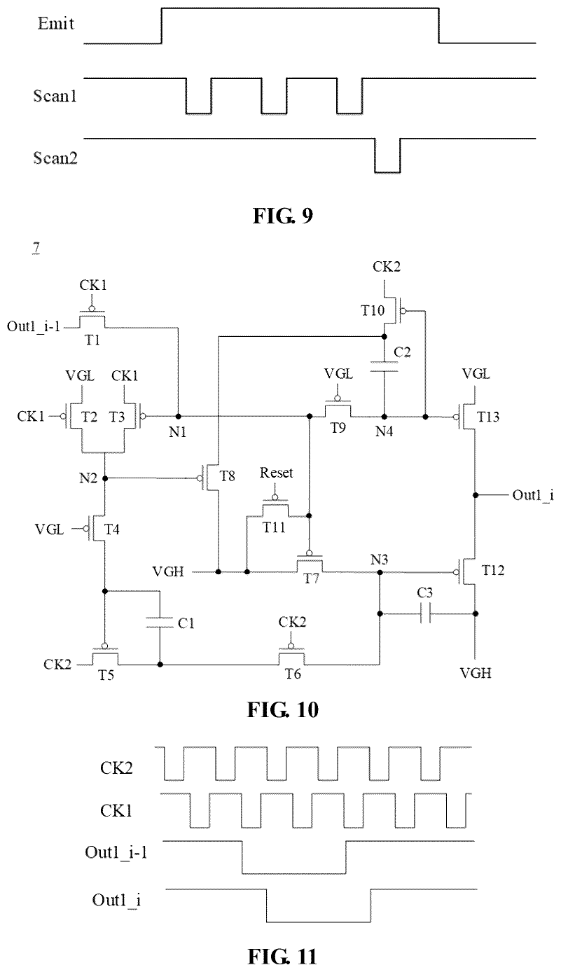

In a feasible embodiment, as shown in FIG. 9, which is a timing diagram according to another embodiment of the present application, within the time covered by one disable level of the light-emitting control signal, the first scanning signal has at least two enable levels, and the enable levels in the first scanning signal are prior to the enable level of the second scanning signal.

In this driving method, the first scanning signal performs multi-pulse driving, and the driving transistor M1 is reset multiple times before data write. This can also increase the total reset time for the driving transistor M1, thereby effectively solving the problems of afterimages and brightness difference in the first frame. Moreover, the first scanning signal may still follow the driving with the shift registers corresponding to the first scanning signal in the related art, so additional shift registers are not required for the first scanning signal, and the panel design is adjusted little.

In a feasible embodiment, with reference to FIG. 4, the display panel further includes a first shift register 6, the first shift register 6 includes a plurality of first shift units 7 that are cascaded, and the first shift unit 7 is electrically connected to the first scanning line Scan1 to output the first scanning signal to the connected first scanning line Scan1.

The display panel further includes a second shift register 8, the second shift register 8 includes a plurality of second shift units 9 that are cascaded, and the second shift unit 9 is electrically connected to the second scanning line Scan2 to output the second scanning signal to the connected second scanning line Scan2.

The display panel further includes a third shift register 10, the third shift register 10 includes a plurality of third shift units 11 that are cascaded, and the third shift unit 11 is electrically connected to the light-emitting control line Emit to output the light-emitting control signal to the connected light-emitting control line Emit.

In the embodiments of the present application, separate shift registers are configured for driving the first scanning line Scan1 and the second scanning line Scan2, whereby the timing of the first scanning signal and the second scanning signal can be designed differently, for example, the number of pulses of the first scanning signal or the low level duration of a single pulse can be separately flexibly adjusted, so as to better achieve the purposes of eliminating afterimages and brightness difference in the first frame and preventing the occurrence of black-on-bright bars.

The first shift unit 7, the second shift unit 9, and the third shift unit 11 may be of different circuit structures, so as to output signals of different waveforms as the first scanning signal, the second scanning signal, and the light-emitting control signal, respectively.

The embodiments of the present application illustrate one circuit structure of the first shift unit 7 and the second shift unit 9 respectively below.

In one circuit structure that may be used for the first shift unit 7, as shown in FIGS. 10 and 11, FIG. 10 is a schematic structural diagram of the first shift unit 7 according to an embodiment of the present application, and FIG. 11 is a timing diagram corresponding to FIG. 10. The first shift unit 7 includes:
a first transistor T1, the first transistor T1 having a gate electrically connected to a first clock line CK1, a first electrode electrically connected to an output terminal Out1_i-1 of the previous first shift unit 7, and a second electrode electrically connected to a first node N1;
a second transistor T2, the second transistor T2 having a gate electrically connected to the first clock line CK1, a first electrode electrically connected to a low potential signal line VGL, and a second electrode electrically connected to a second node N2;
a third transistor T3, the third transistor T3 having a gate electrically connected to the first node N1, a first electrode electrically connected to the first clock line CK1, and a second electrode electrically connected to the second node N2;
a fourth transistor T4, the fourth transistor T4 having a gate electrically connected to the low potential signal line VGL and a first electrode electrically connected to the second node N2;
a fifth transistor T5, the fifth transistor T5 having a gate electrically connected to a second electrode of the fourth transistor T4, and a first electrode electrically connected to the second clock line CK2;
a sixth transistor T6, the sixth transistor T6 having a gate electrically connected to the second clock line CK2, a first electrode electrically connected to a second electrode of the fifth transistor T5, and a second electrode electrically connected to a third node N3;
a seventh transistor T7, the seventh transistor T7 having a gate electrically connected to the first node N1, a first electrode electrically connected to a high potential signal line VGH, and a second electrode electrically connected to the third node N3;
an eighth transistor T8, the eighth transistor T8 having a gate electrically connected to the second node N2, and a first electrode electrically connected to the high potential signal line VGH;
a ninth transistor T9, the ninth transistor T9 having a gate electrically connected to the low potential signal line VGL, a first electrode electrically connected to the first node N1, and a second electrode electrically connected to a fourth node N4;
a tenth transistor T10, the tenth transistor T10 having a gate electrically connected to the fourth node N4, a first electrode electrically connected to the second clock line CK2, and a second electrode electrically connected to a second electrode of the eighth transistor T8;
an eleventh transistor T11, the eleventh transistor T11 having a gate electrically connected to a control line Reset, a first electrode electrically connected to the high potential signal line VGH, and a second electrode electrically connected to the first node N1;
a twelfth transistor T12, the twelfth transistor T12 having a gate electrically connected to the third node N3, a first electrode electrically connected to the high potential signal line VGH, and a second electrode electrically connected to an output terminal Out1_i;
a thirteenth transistor T13, the thirteenth transistor T13 having a gate electrically connected to the fourth node N4, a first electrode electrically connected to the low potential signal line VGL, and a second electrode electrically connected to the output terminal Out1_i;
a first capacitor C1, the first capacitor C1 having a first electrode plate electrically connected to the gate of the fifth transistor T5, and a second electrode plate electrically connected to the second electrode of the fifth transistor T5;
a second capacitor C2, the second capacitor C2 having a first electrode plate electrically connected to the second electrode of the tenth transistor T10, and a second electrode plate electrically connected to the fourth node N4; and
a third capacitor C3, the third capacitor C3 having a first electrode plate electrically connected to the third node N3, and a second electrode plate electrically connected to the high potential signal line VGH.

It should be noted that FIG. 10 only shows an example of one structure of the first shift unit 7. In other optional embodiments of the present application, other structures of the first shift unit 7 may also be used to output signal waveforms required by the first scanning line Scan1.

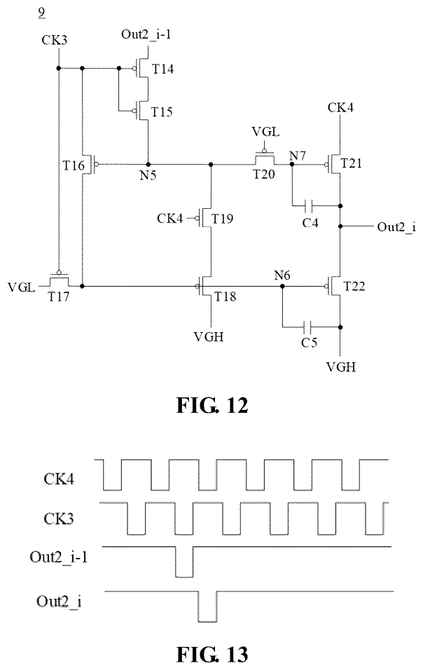

In one circuit structure that may be used for the second shift unit 9, as shown in FIGS. 12 and 13, FIG. 12 is a schematic structural diagram of the second shift unit 9 according to an embodiment of the present application, and FIG. 13 is a timing diagram corresponding to FIG. 12. The second shift unit 9 includes:
a fourteenth transistor T14, the fourteenth transistor T14 having a gate electrically connected to a third clock line CK3, and a first electrode electrically connected to an output terminal Out2_i-1 of the previous second shift unit 9;
a fifteenth transistor T15, the fifteenth transistor T15 having a gate electrically connected to the third clock line CK3, a first electrode electrically connected to a second electrode of the fourteenth transistor T14, and a second electrode electrically connected to a fifth node N5;
a sixteenth transistor T16, the sixteenth transistor T16 having a gate electrically connected to the fifth node N5, a first electrode electrically connected to the third clock line CK3, and a second electrode electrically connected to a sixth node N6;
a seventeenth transistor T17, the seventeenth transistor T17 having a gate electrically connected to the third clock line CK3, a first electrode electrically connected to the low potential signal line VGL, and a second electrode electrically connected to the sixth node N6;
an eighteenth transistor T18, the eighteenth transistor T18 having a gate electrically connected to the sixth node N6, and a first electrode electrically connected to the high potential signal line VGH;
a nineteenth transistor T19, the nineteenth transistor T19 having a gate electrically connected to a fourth clock line CK4, a first electrode electrically connected to a second electrode of the eighteenth transistor T18, and a second electrode electrically connected to the fifth node N5;
a twentieth transistor T20, the twentieth transistor T20 having a gate electrically connected to the low potential signal line VGL, a first electrode electrically connected to the fifth node N5, and a second electrode electrically connected to a seventh node N7;
a twenty-first transistor T21, the twenty-first transistor T21 having a gate electrically connected to the seventh node N7, a first electrode electrically connected to the fourth clock line CK4, and a second electrode electrically connected to an output terminal Out_i;
a twenty-second transistor T22, the twenty-second transistor T22 having a gate electrically connected to the sixth node N6, a first electrode electrically connected to the high potential signal line VGH, and a second electrode electrically connected to the output terminal Out_i;
a fourth capacitor C4, the fourth capacitor C4 having a first electrode plate electrically connected to the seventh node N7, and a second electrode plate electrically connected to the output terminal Out_i; and
a fifth capacitor C5, the fifth capacitor C5 having a first electrode plate electrically connected to the sixth node N6, and a second electrode plate electrically connected to the high potential signal line VGH.

It should be noted that FIG. 12 only shows an example of one structure of the second shift unit 9. In other optional embodiments of the present application, other structures of the second shift unit 9 may also be used to output signal waveforms required by the second scanning line Scan2.

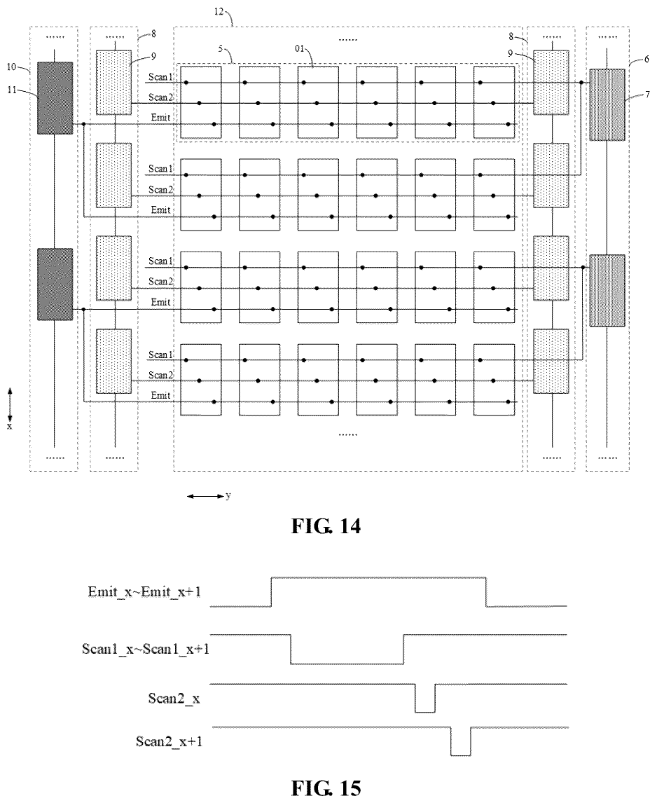

In a feasible embodiment, as shown in FIGS. 14 and 15, FIG. 14 is a schematic structural diagram of a display panel according to another embodiment of the present application, and FIG. 15 is a timing diagram according to yet another embodiment of the present application. The display panel further includes a plurality of circuit rows 5 arranged along the first direction x, and the circuit row 5 includes a plurality of pixel circuits 01 arranged along the second direction y intersecting with the first direction x.

One first shift unit 7 is electrically connected to the first scanning lines Scan1 corresponding to m circuit rows 5, and one third shift unit 11 is electrically connected to the light-emitting control lines Emit corresponding to m circuit rows 5, where m≥2.

FIGS. 14 and 15 illustrate m=2 as an example. In FIG. 15, Emit_x˜Emit_x+1 represent light-emitting control signals corresponding to the xth circuit row 5 and the (x+1)th circuit row 5, Scan1_x˜Scan1_x+1 represent first scanning signals corresponding to the xth circuit row 5 and the (x+1)th circuit row 5, Scan2_x represents a second scanning signal corresponding to the xth circuit row 5, and Scan2_x+1 represents a second scanning signal corresponding to the (x+1)th circuit row 5.

In such structure, one first shift unit 7 is configured to output first scanning signals to the m circuit rows 5, and one third shift unit 11 is configured to output light-emitting control signals to the m circuit rows 5. Such arrangement can decrease the quantity of shift units required in the first shift register 6 and the third shift register 10 to achieve narrow bezel design, and can decrease the quantity of pulses output by the first shift register 6 and the third shift register 10 to reduce power consumption.

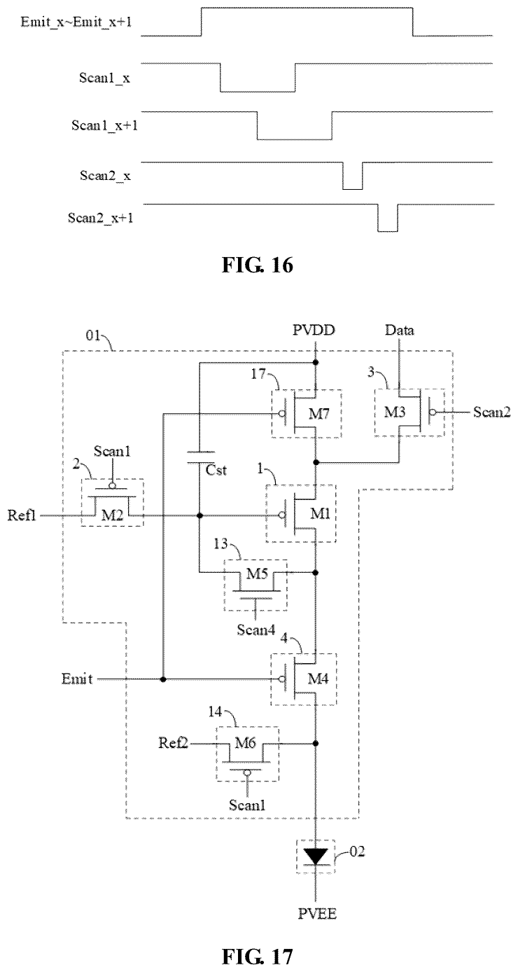

In addition, when one third shift unit 11 is electrically connected to the light-emitting control lines Emit corresponding to the m circuit rows 5, if one first shift unit 7 is electrically connected only to the first scanning line Scan1 corresponding to one circuit row 5, as shown in FIG. 16, which is a timing diagram according to yet another embodiment of the present application, and one high level of the light-emitting control signal needs to cover the low levels of m first scanning signals corresponding one to one with the m circuit rows 5, in the case where the duration of the high level of the light-emitting control signal is definite, the duration of the low level of the first scanning signal corresponding to the single circuit row 5 will be relatively short. In the embodiments of the present application, one first shift unit 7 is also electrically connected to the first scanning lines Scan1 corresponding to the m circuit rows 5, and the m circuit rows 5 share one first scanning signal. Therefore, the duration of a single low level of the first scanning signal can be extended to increase the reset time.

Further, considering that excessive m affects the load and voltage drop of signals, m may be designed to be equal to 2 in the embodiments of the present application.

Moreover, in the embodiments of the present application, with reference to FIG. 14, one second shift unit 9 may be electrically connected only to the second scanning line Scan2 corresponding to one circuit row 5, so that the pixel circuits 01 in each circuit row 5 can accurately receive required data voltage, thereby ensuring display accuracy.

In a feasible embodiment, with reference to FIG. 14, the display panel includes two second shift registers 8 electrically connected to the second scanning line Scan2 on both sides of the second scanning line Scan2.

The second scanning line Scan2 is used to control the data write transistor M3 to write data voltage, and the data voltage determines the magnitude of driving current, so the requirement for the stability of driving force of the second scanning line Scan2 is higher. In this regard, in the embodiments of the present application, two sets of second shift registers 8 are used for bilateral driving on the second scanning line Scan2, so as to improve the write stability and accuracy of the second scanning signal.

In a feasible embodiment, with reference to FIG. 14, the display panel further includes a display area 12.

The display panel includes two second shift registers 8. The first shift register 6 and one of the second shift registers 8 are located on one side of the display area 12, and the third shift register 10 and the other one of the second shift registers 8 are located on the other side of the display area 12.

In such arrangement, two of the four sets of shift registers are located on one side of the display area 12, and the other two sets are located on the other side of the display area 12, whereby the distribution of the shift registers is more rational, and the left and right border design of the display panel can be optimized.

In other optional embodiments of the present application, the shift registers may be designed in other ways. For example, in display panels with lower requirements for border width, such as display panels of vehicle displays, one first shift unit 7 is electrically connected to the first scanning line Scan1 corresponding to one circuit row 5, one second shift unit 9 is electrically connected to the second scanning line Scan2 corresponding to one circuit row 5, and one third shift unit 11 is electrically connected to the light-emitting control line Emit corresponding to one circuit row 5. Further, the display panel may include two sets of first shift registers 6, two sets of second shift registers 8, and two sets of third shift registers 10, the two sets of first shift registers 6 are connected to the first scanning line Scan1 on both sides of the first scanning line Scan1 respectively, the two sets of second shift registers 8 are connected to the second scanning line Scan2 on both sides of the second scanning line Scan2 respectively, and the two sets of third shift registers 10 are connected to the light-emitting control line Emit on both sides of the light-emitting control line Emit respectively.

With reference to FIG. 5, the pixel circuit 01 further includes a threshold compensation circuit 13, a first terminal of the threshold compensation circuit 13 is electrically connected to the second terminal of the driving circuit 1, and a second terminal of the threshold compensation circuit 13 is electrically connected to the control terminal of the driving circuit 1. More specifically, the threshold compensation circuit 13 includes a threshold compensation transistor M5, and the threshold compensation transistor M5 has a first electrode electrically connected to the second electrode of the driving transistor M1 and a second electrode electrically connected to the gate of the driving transistor M1.

In one structure, combining FIGS. 4 and 5, a control terminal of the threshold compensation circuit 13 is electrically connected to the second scanning line Scan2, that is, a gate of the threshold compensation transistor M5 is electrically connected to the second scanning line Scan2. At this point, the threshold compensation transistor M5 may be of the same type as the first reset transistor M2 and the data write transistor M3, such as an LTPS transistor. The threshold compensation transistor M5 is turned on in response to the low level of the second scanning signal, and further writes the data voltage written by the second electrode of the driving transistor M1 into the gate of the driving transistor M1. This structure does not require additional scanning lines for the threshold compensation circuit 13, thereby simplifying structural design.

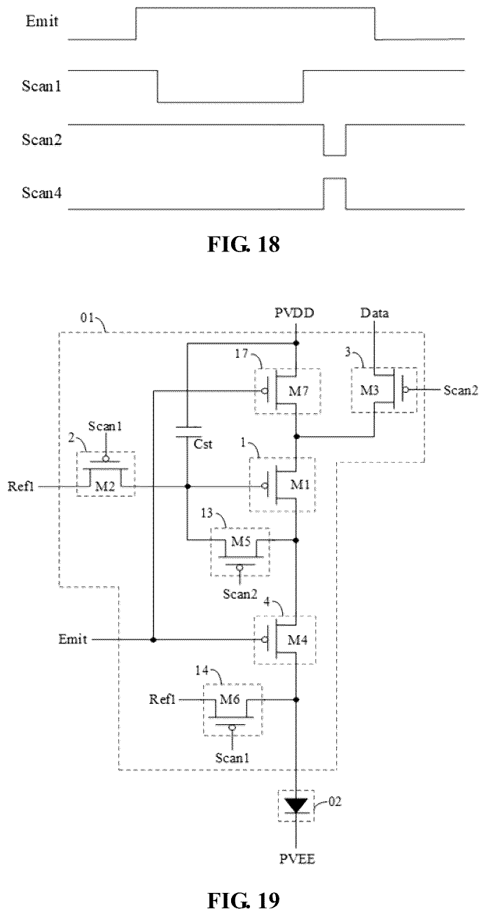

Alternatively, in another structure, as shown in FIGS. 17 and 18, FIG. 17 is a schematic structural diagram of a pixel circuit 01 according to another embodiment of the present application, and FIG. 18 is a timing diagram according to yet another embodiment of the present application. The control terminal of the threshold compensation circuit 13 is electrically connected to a fourth scanning line Scan4 configured to provide a fourth scanning signal, that is, the gate of the threshold compensation transistor M5 is electrically connected to the fourth scanning line Scan4. The fourth scanning signal has a high enable level and a low disable level. Moreover, the time covered by the high level of the fourth scanning signal overlaps with the time covered by the low level of the second scanning signal. The threshold compensation transistor M5 is turned on in response to the high level of the fourth scanning signal, and further writes the data voltage written by the second electrode of the driving transistor M1 into the gate of the driving transistor M1. At this time, the threshold compensation transistor M5 is an N-type transistor. For example, to reduce the impact of off-state leakage current of the threshold compensation transistor M5 on the gate potential of the driving transistor M1, the threshold compensation transistor M5 may be an indium gallium zinc oxide (IGZO) transistor.

In a feasible embodiment, as shown in FIG. 5, the display panel further includes a second reset circuit 14, a first terminal of the second reset circuit 14 is electrically connected to a second reset line Ref2, and a second terminal of the second reset circuit 14 is electrically connected to the light-emitting element 02, the first reset line Ref1 and the second reset line Ref2 provide different reset voltages.

More specifically, the second reset circuit 14 includes a second reset transistor M6, and the second reset transistor M6 has a first electrode electrically connected to the second reset line Ref2 and a second electrode electrically connected to the light-emitting element 02. When the second reset transistor M6 is turned on, a second reset voltage is written into the light-emitting element 02 to reset an anode of the light-emitting element 02.

By using different reset voltages to reset the driving transistor M1 and the light-emitting element 02, the driving is more flexible. For example, the second reset voltage may be designed to be lower to better avoid the problem of sub-pixel crosstalk.

Alternatively, in another feasible embodiment, as shown in FIG. 19, which is a schematic structural diagram of a pixel circuit 01 according to yet another embodiment of the present application, the first terminal of the second reset circuit 14 may be electrically connected to the first reset line Ref1, whereby only one reset line is configured for the first reset circuit 2 and the second reset circuit 14 to simplify the structural design.

In a feasible embodiment, with reference to FIGS. 5 and 6, the display panel further includes a second reset circuit 14, a control terminal of the second reset circuit 14 receives a scanning signal, a first terminal of the second reset circuit 14 receives a reset voltage, and a second terminal of the second reset circuit 14 is electrically connected to the light-emitting element 02.

Within the time covered by one disable level of the light-emitting control signal, the total duration of enable levels in the scanning signal received by the second reset circuit 14 is longer than the duration of the enable level of the second scanning signal, thereby increasing the reset time for the light-emitting element 02 and resetting the anode potential of the light-emitting element 02 more thoroughly. Before light emission, the anode voltages of the light-emitting elements 02 in different sub-pixels are configured to a consistent initial state, which helps to improve display uniformity.

In a feasible embodiment, with reference to FIGS. 5 and 6, the control terminal of the second reset circuit 14 is electrically connected to the first scanning line Scan1, and the first scanning signal drives the second reset circuit 14 to increase the reset time for the light-emitting element 02, without configuring an additional scanning line for the second reset circuit 14.

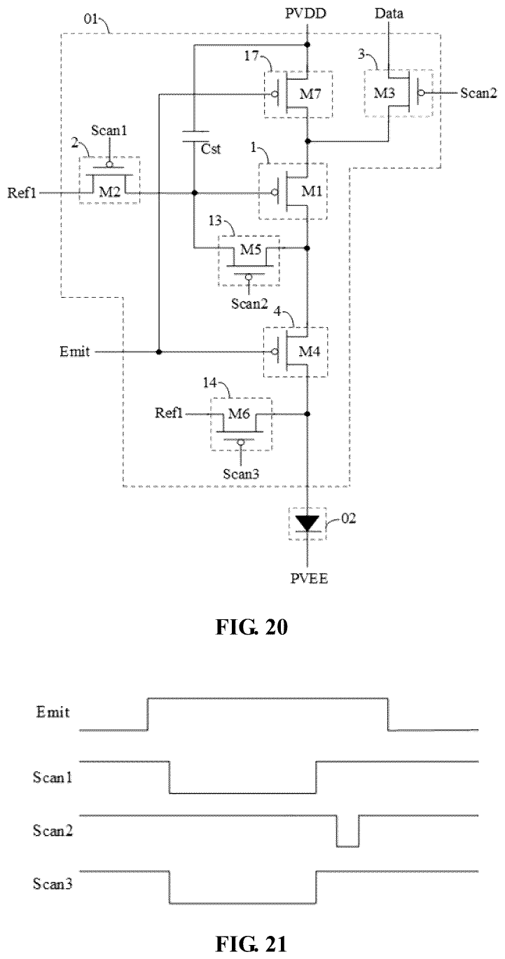

Alternatively, in another feasible embodiment, as shown in FIG. 20, which is a schematic structural diagram of a pixel circuit 01 according to yet another embodiment of the present application, the control terminal of the second reset circuit 14 is electrically connected to a third scanning line Scan3 configured to provide a third scanning signal.

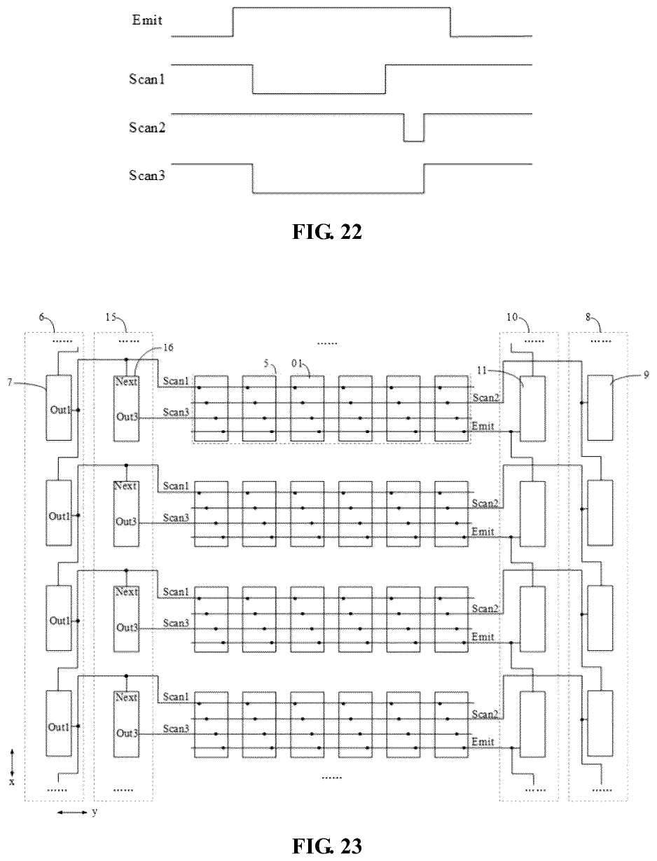

The second reset circuit 14 is driven by the separate third scanning line Scan3, whereby the reset time for the light-emitting element 02 may be designed separately. For example, as shown in FIG. 21, which is a timing diagram according to yet another embodiment of the present application, the waveform of the third scanning signal may be the same as the waveform of the first scanning signal. Alternatively, as shown in FIG. 22, which is a timing diagram according to yet another embodiment of the present application, the waveform of the third scanning signal may be different from the waveform of the first scanning signal. For example, in the working process of the pixel circuit 01, the turned-on time of the first reset transistor M2 does not overlap with the turned-on time of the data write transistor M3 and the threshold compensation transistor M5, otherwise the gate potential of the driving transistor M1 will be disordered. Therefore, the low level of the first scanning signal do not overlap with the low level of the second scanning signal. The turned-on time of the second reset transistor M6 may overlap with the turned-on time of the data write transistor M3 and the threshold compensation transistor M5. Therefore, when the second reset transistor M6 is connected to the third scanning line Scan3, the duration of the low level of the third scanning signal may be designed to be longer, and the low level of the third scanning signal may overlap with the low level of the first scanning signal and the low level of the second scanning signal, so as to achieve a longer reset time for the light-emitting element 02.

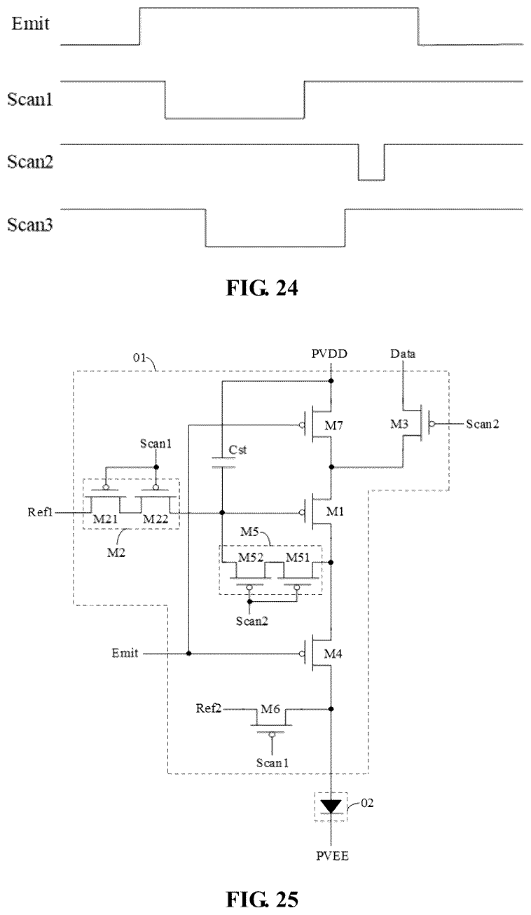

Further, as shown in FIGS. 23 and 24, FIG. 23 is a schematic structural diagram of a display panel according to yet another embodiment of the present application, and FIG. 24 is a timing diagram according to yet another embodiment of the present application. The display panel further includes a plurality of circuit rows 5 arranged along the first direction x, and the circuit row 5 includes a plurality of pixel circuits 01 arranged along the second direction y intersecting with the first direction x.

The display panel further includes a first shift register 6, the first shift register 6 includes a plurality of first shift units 7 that are cascaded, and an output terminal of the first shift unit 7 is electrically connected to the first scanning line Scan1 corresponding to at least one circuit row 5.

The display panel further includes a fourth shift register 15, the fourth shift register 15 includes a plurality of fourth shift units 16 that are cascaded, and an output terminal Out3 of the fourth shift unit 16 is electrically connected to the third scanning line Scan3 corresponding to at least one circuit row 5.

For the first shift unit 7 and the fourth shift unit 16 corresponding to the same circuit row 5, the output terminal Out1 of the first shift unit 7 is also electrically connected to a shift control terminal Next of the fourth shift unit 16.

In this driving mode, the third scanning line Scan3 is driven by the separate fourth shift register 15, and the signals output by different shift registers only need to be transmitted to one scanning line, resulting in a small voltage drop of the scanning signals.

Generally, in the plurality of shift units that are cascaded in the shift register, the signal output by the output terminal of the previous shift unit also serves as a shift control signal of the shift control terminal of the next shift unit, thereby enabling the plurality of shift units to output enable levels sequentially. To drive the first shift unit to work normally, the shift control terminal of the first shift unit needs to be electrically connected to a frame start signal line. After the frame start signal line outputs a signal, the first shift unit starts outputting a signal under the action of the frame start signal, a clock signal, etc. The signal output by the first shift unit serves as a shift signal of the second shift unit to drive the second shift unit to work, so that the second shift unit outputs a signal sequentially. Then, the third, fourth, . . . , until the last shift unit outputs a signal sequentially.

In the above structure, the shift control signal of the fourth shift unit 16 is not provided by the output terminal Out3 of the previous fourth shift unit 16, but by the output terminal Out1 of the first shift unit 7. By such arrangement, only the signal output by the first shift unit 7 serves as the frame start signal of the first fourth shift units 16, without configuring an additional frame start signal line for the fourth shift register 15, thereby decreasing the quantity of traces.

In other optional embodiments of the present application, the control terminal of the second reset circuit 14 may be electrically connected to the second scanning line Scan2.

In the embodiments of the present application, with reference to FIG. 5, the pixel circuit 01 further includes a second light-emitting control circuit 17, a control terminal of the second light-emitting control circuit 17 is electrically connected to the light-emitting control line Emit, a first terminal of the second light-emitting control circuit 17 is electrically connected to a power line PVDD, and a second terminal of the second light-emitting control circuit 17 is electrically connected to the first terminal of the driving circuit 1.

More specifically, the second light-emitting control circuit 17 includes a second light-emitting control transistor M7, and the second light-emitting control transistor M7 has a gate electrically connected to the light-emitting control line Emit, a first electrode electrically connected to the power line PVDD, and a second electrode electrically connected to the first electrode of the driving transistor M1.

The pixel circuit 01 further includes a storage capacitor Cst, and the storage capacitor Cst has a first electrode plate electrically connected to the power line PVDD and a second electrode plate electrically connected to the gate of the driving transistor M1.

In the embodiments of the present application, in order to reduce the impact of off-state leakage current of the first reset transistor M2 and the threshold compensation transistor M5 on the gate potential of the driving transistor M1, as shown in FIG. 25, which is a schematic structural diagram of a pixel circuit according to yet another embodiment of the present application, the first reset transistor M2 includes a first sub-transistor M21 and a second sub-transistor M22, a gate of the first sub-transistor M21 and a gate of the second sub-transistor M22 are electrically connected to the first scanning line Scan1, a first electrode of the first sub-transistor M21 is electrically connected to the first reset line Ref1, a second electrode of the first sub-transistor M21 is electrically connected to a first electrode of the second sub-transistor M22, and a second electrode of the second sub-transistor M22 is electrically connected to the gate of the driving transistor M1. The threshold compensation transistor M5 includes a third sub-transistor M51 and a fourth sub-transistor M52, gates of the third sub-transistor M51 and the fourth sub-transistor M52 are electrically connected to the second scanning line Scan2, a first electrode of the third sub-transistor M51 is electrically connected to the second electrode of the driving transistor M1, a second electrode of the third sub-transistor M51 is electrically connected to a first electrode of the fourth sub-transistor M52, and a second electrode of the fourth sub-transistor M52 is electrically connected to the gate of the driving transistor M1.

Based on the same inventive concept, embodiments of the present application further provide a driving method for a display panel. With reference to FIGS. 4 to 6, the display panel includes a pixel circuit 01. The pixel circuit 01 includes a driving circuit 1, a first reset circuit 2, a data write circuit 3, and a first light-emitting control circuit 4.

A control terminal of the first reset circuit 2 is electrically connected to a first scanning line Scan1 configured to provide a first scanning signal, a first terminal of the first reset circuit 2 is electrically connected to a first reset line Ref1, and a second terminal of the first reset circuit 2 is electrically connected to a control terminal of the driving circuit 1.

A control terminal of the data write circuit 3 is electrically connected to a second scanning line Scan2 configured to provide a second scanning signal, a first terminal of the data write circuit 3 is electrically connected to a data line Data, and a second terminal of the data write circuit 3 is electrically connected to a first terminal of the driving circuit 1.

A control terminal of the first light-emitting control circuit 4 is electrically connected to a light-emitting control line Emit configured to provide a light-emitting control signal, a first terminal of the first light-emitting control circuit 4 is electrically connected to a second terminal of the driving circuit 1, and a second terminal of the first light-emitting control circuit 4 is electrically connected to the light-emitting element 02.

Enable levels of the first scanning signal and the second scanning signal are low levels.

The driving method includes: within a time covered by one disable level of the light-emitting control signal, controlling the second scanning signal to output one enable level, and controlling the total duration of the enable levels in the first scanning signal to be longer than the duration of the enable level of the second scanning signal.

In the embodiments of the present application, within the time covered by the single high level of the light-emitting control signal, the total duration of the low levels in the first scanning signal is longer than the duration of the low level of the second scanning signal, so the first reset transistor M2 can reset the driving transistor M1 for a longer time, thereby improving the reset capability for the driving transistor M1, restoring the driving transistor to its initial working state to a greater extent, and restoring the threshold voltage of the driving transistor to a normal level. Furthermore, during gray-scale switching, the driving transistor M1 may be quickly in a normal state, thereby effectively solving the problems of short-term afterimages and brightness difference in the first frame. Meanwhile, within the time covered by the single high level of the light-emitting control signal, the second scanning signal has only one low level, that is, voltage is written to the driving transistor M1 only once, and the written voltage is the data voltage required by the driving transistor. In this way, the node potential of the driving transistor M1 will not be affected by a display signal in the previous circuit row, thereby avoiding black-on-bright bars.

In addition, compared to the related art, the second scanning signal outputs fewer pulses in the embodiments of the present application, which can reduce panel power consumption to a certain extent.

In a feasible embodiment, combining FIGS. 5 and 6, within the time covered by one disable level of the light-emitting control signal, the first scanning signal is controlled to output one enable level, and the enable level of the first scanning signal is prior to the enable level of the second scanning signal.

The duration of the enable level of the first scanning signal is t1, and the duration of the enable level of the second scanning signal is t2, where t1>t2.

Based on this driving method, within the time covered by one disable level of the light-emitting control signal, both the first scanning signal and the second scanning signal perform single-pulse driving. The single low level of the first scanning signal has relatively long duration, and the first scanning signal drives the first reset transistor M2 to be turned on for a long time and continuously resets the driving transistor M1 for a relatively long time, so that the driving transistor M1 is restored to its initial working state to a greater extent, thereby effectively solving the problems of afterimages and brightness difference in the first frame during gray-scale switching. Moreover, compared to the related art, such driving results in fewer pulses output by the first scanning signal, which can further reduce panel power consumption.

Further, 2×t2≤t1≤20×t2.

Based on the previous analysis, setting the minimum value of t1 to 2×t2 can ensure sufficient reset time for the driving transistor M1. Further, setting the maximum value of t1 to 20×t2 can ensure optimal SVM and avoid human eye recognition of flicker.

In a feasible embodiment, with reference to FIG. 6, a time point when the light-emitting control signal transitions from the enable level to the disable level is a first time point p1, a time point when the first scanning signal transitions from the disable level to the enable level is a second time point p2, and the interval between the first time point p1 and the second time point p2 is ΔT1, where 0<ΔT1≤1H.

A time point when the first scanning signal transitions from the enable level to the disable level is a third time point p3, a time point when the second scanning signal transitions from the disable level to the enable level is a fourth time point p4, and the interval between the third time point p3 and the fourth time point p4 is ΔT2, where 0<ΔT2≤1H.

$$H = \frac{1}{f \times n} ,$$

where n represents the number of rows of the pixel circuits 01, and f represents a base frequency or a current driving frequency of the display panel.

When ΔT1 and ΔT2 satisfy the above limitations, the interval between the low transition of the first scanning signal and the high transition of the light-emitting control signal is at most 1H, and the time interval between the two is relatively short. Meanwhile, the interval between the high transition of the first scanning signal and the low transition of the second scanning signal is also at most 1H, and the time interval between the two is also relatively short. Then, under the condition that the high level of the light-emitting control signal has definite duration, the duration of the low level of the first scanning signal can be further extended to increase the reset time.

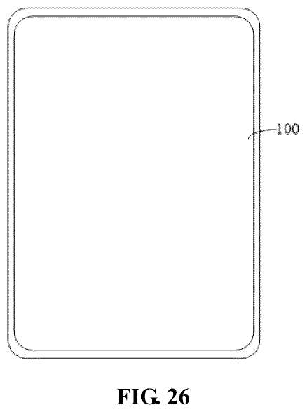

Based on the same inventive concept, embodiments of the present application further provides a display apparatus, as shown in FIG. 26, which is a schematic structural diagram of a display apparatus according to an embodiment of the present application. The display apparatus includes the foregoing display panel 100. The display apparatus shown in FIG. 26 is merely illustrative. The display apparatus may be any electronic device with display functions, such as a mobile phone, a tablet, a laptop, an e-book, or a television.

The foregoing descriptions are merely preferred embodiments of the present application, but are not intended to limit the present application. Any modification, equivalent substitution, or improvement made without departing from the spirit and principle of the present application shall fall within the scope of protection of the present application.

Finally, it should be noted that the above embodiments are merely used to illustrate, but not to limit, the technical solution of the present application; although the present application is described in detail with reference to the foregoing embodiments, those skilled in the art should understand that they can still modify the technical solutions described in the foregoing embodiments, or equivalently replace some or all of the technical features therein; and these modifications or substitutions do not make the essence of the corresponding technical solutions deviate from the scope of the technical solutions of the embodiments of the present application.

What is claimed is:

1. A display panel, comprising a pixel circuit comprising:
a driving circuit,
a first reset circuit, a control terminal of the first reset circuit being electrically connected to a first scanning line configured to provide a first scanning signal, a first terminal of the first reset circuit being electrically connected to a first reset line, and a second terminal of the first reset circuit being electrically connected to a control terminal of the driving circuit,
a data write circuit, a control terminal of the data write circuit being electrically connected to a second scanning line configured to provide a second scanning signal, a first terminal of the data write circuit being electrically connected to a data line, and a second terminal of the data write circuit being electrically connected to a first terminal of the driving circuit, and
a first light-emitting control circuit, a control terminal of the first light-emitting control circuit being electrically connected to a light-emitting control line configured to provide a light-emitting control signal, a first terminal of the first light-emitting control circuit being electrically connected to a second terminal of the driving circuit, and a second terminal of the first light-emitting control circuit being electrically connected to a light-emitting element, wherein
enable levels of the first scanning signal and the second scanning signal are low levels;
within a time period covered by one disable level of the light-emitting control signal, the second scanning signal has one enable level, and a total duration of the enable levels in the first scanning signal is longer than the duration of the enable level of the second scanning signal.

2. The display panel according to claim 1, wherein
within the time period covered by one disable level of the light-emitting control signal, the first scanning signal has one enable level, and the enable level of the first scanning signal is prior to the enable level of the second scanning signal;
the duration of the enable level of the first scanning signal is t1, and the duration of the enable level of the second scanning signal is t2, where t1>t2.

3. The display panel according to claim 2, wherein
$$t 1 \geq 2 \times t 2.$$

4. The display panel according to claim 3, wherein
$$t 1 \leq 20 \times t 2 .$$

5. The display panel according to claim 2, wherein
a time point when the light-emitting control signal transitions from the enable level to the disable level is a first time point, a time point when the first scanning signal transitions from the disable level to the enable level is a second time point, and the interval between the first time point and the second time point is ΔT1, where 0<ΔT1≥1H; and
a time point when the first scanning signal transitions from the enable level to the disable level is a third time point, a time point when the second scanning signal transitions from the disable level to the enable level is a fourth time point, and the interval between the third time point and the fourth time point is ΔT2, where 0<ΔT2≥1H,
where
$$H = \frac{1}{f \times n} ,$$
n represents the number of rows of the pixel circuits in the display panel, and f represents a base frequency or a current driving frequency of the display panel.

6. The display panel according to claim 1, wherein
within the time covered by one disable level of the light-emitting control signal, the first scanning signal has at least two enable levels prior to the enable level of the second scanning signal.

7. The display panel according to claim 1, further comprising:
a first shift register, comprising a plurality of first shift units that are cascaded and electrically connected to the first scanning line;
a second shift register, comprising a plurality of second shift units that are cascaded and electrically connected to the second scanning line; and
a third shift register, comprising a plurality of cascaded third shift units electrically connected to the light-emitting control line.

8. The display panel according to claim 7, further comprising a plurality of circuit rows arranged along a first direction, the circuit rows each comprising a plurality of pixel circuits arranged along a second direction intersecting with the second direction,
wherein one of the first shift units is electrically connected to the first scanning lines corresponding to m ones of the circuit rows, and one of the third shift units is electrically connected to the light-emitting control lines corresponding to the m ones of the circuit rows, where m≥2.

9. The display panel according to claim 7, wherein
the display panel comprises two second shift registers electrically connected to the second scanning line on both sides of the second scanning line.

10. The display panel according to claim 7, further comprising:
a display area; and
two second shift registers, wherein the first shift register and one of the second shift registers are located on one side of the display area, and the third shift register and the other one of the second shift registers are located on the other side of the display area.

11. The display panel according to claim 1, further comprising a second reset circuit, a first terminal of the second reset circuit being electrically connected to a second reset line, and a second terminal of the second reset circuit being electrically connected to the light-emitting element, wherein the first reset line and the second reset line provide different reset voltages.

12. The display panel according to claim 1, further comprising a second reset circuit, a control terminal of the second reset circuit being configured to receive a scanning signal, a first terminal of the second reset circuit being configured to receive a reset voltage, and a second terminal of the second reset circuit being electrically connected to the light-emitting element,
wherein within the time covered by one disable level of the light-emitting control signal, the total duration of enable levels in the scanning signal received by the second reset circuit is longer than the duration of the enable level of the second scanning signal.

13. The display panel according to claim 12, wherein
the control terminal of the second reset circuit is electrically connected to the first scanning line.

14. The display panel according to claim 12, wherein
the control terminal of the second reset circuit is electrically connected to a third scanning line.

15. The display panel according to claim 14, further comprising:
a plurality of circuit rows arranged along a first direction, the circuit rows each comprising a plurality of pixel circuits arranged along a second direction intersecting with the first direction;
a first shift register, comprising a plurality of first shift units that are cascaded, output terminals of the first shift units being electrically connected to the first scanning line corresponding to at least one of the circuit rows; and
a fourth shift register, comprising a plurality of cascaded fourth shift units, output terminals of the fourth shift units being electrically connected to the third scanning line corresponding to at least one of the circuit rows,
wherein for the first shift unit and the fourth shift unit corresponding to the same circuit row, the output terminal of the first shift unit is also electrically connected to a shift control terminal of the fourth shift unit.

16. A driving method for a display panel, the display panel comprising a pixel circuit comprising:
a driving circuit;
a first reset circuit, a control terminal of the first reset circuit being electrically connected to a first scanning line configured to provide a first scanning signal, a first terminal of the first reset circuit being electrically connected to a first reset line, and a second terminal of the first reset circuit being electrically connected to a control terminal of the driving circuit;
a data write circuit, a control terminal of the data write circuit being electrically connected to a second scanning line configured to provide a second scanning signal, a first terminal of the data write circuit being electrically connected to a data line, and a second terminal of the data write circuit being electrically connected to a first terminal of the driving circuit; and
a first light-emitting control circuit, a control terminal of the first light-emitting control circuit being electrically connected to a light-emitting control line configured to provide a light-emitting control signal, a first terminal of the first light-emitting control circuit being electrically connected to a second terminal of the driving circuit, and a second terminal of the first light-emitting control circuit being electrically connected to a light-emitting element, wherein enable levels of the first scanning signal and the second scanning signal are low levels;
the driving method comprising:
controlling, within the time covered by one disable level of the light-emitting control signal, the second scanning signal to output one enable level, and the total duration of the enable levels in the first scanning signal to be longer than the duration of the enable level of the second scanning signal.

17. The driving method according to claim 16, further comprising:
controlling, within the time covered by one disable level of the light-emitting control signal, the first scanning signal to output one enable level, and the enable level of the first scanning signal to be prior to the enable level of the second scanning signal, wherein
the duration of the enable level of the first scanning signal is t1, and the duration of the enable level of the second scanning signal is t2, where t1>t2.

18. The driving method according to claim 17, wherein
$$2 \times t 2 \leq t 1 \leq 20 \times t 2.$$

19. The driving method according to claim 17, wherein
a time point when the light-emitting control signal transitions from the enable level to the disable level is a first time point, a time point when the first scanning signal transitions from the disable level to the enable level is a second time point, and the interval between the first time point and the second time point is ΔT1, where 0<ΔT1≥1H; and
a time point when the first scanning signal transitions from the enable level to the disable level is a third time point, a time point when the second scanning signal transitions from the disable level to the enable level is a fourth time point, and the interval between the third time point and the fourth time point is ΔT2, where 0<ΔT2≥1H,
where
$$H = \frac{1}{f \times n} ,$$
n represents the number of rows of the pixel circuits, and f represents a base frequency or a current driving frequency of the display panel.

20. A display apparatus, comprising a display panel, comprising a pixel circuit comprising:
a driving circuit,
a first reset circuit, a control terminal of the first reset circuit being electrically connected to a first scanning line configured to provide a first scanning signal, a first terminal of the first reset circuit being electrically connected to a first reset line, and a second terminal of the first reset circuit being electrically connected to a control terminal of the driving circuit,
a data write circuit, a control terminal of the data write circuit being electrically connected to a second scanning line configured to provide a second scanning signal, a first terminal of the data write circuit being electrically connected to a data line, and a second terminal of the data write circuit being electrically connected to a first terminal of the driving circuit, and
a first light-emitting control circuit, a control terminal of the first light-emitting control circuit being electrically connected to a light-emitting control line configured to provide a light-emitting control signal, a first terminal of the first light-emitting control circuit being electrically connected to a second terminal of the driving circuit, and a second terminal of the first light-emitting control circuit being electrically connected to a light-emitting element, wherein
enable levels of the first scanning signal and the second scanning signal are low levels;
within a time period covered by one disable level of the light-emitting control signal, the second scanning signal has one enable level, and a total duration of the enable levels in the first scanning signal is longer than the duration of the enable level of the second scanning signal.
